(19) United States
(12) Patent Application Publication
(10) Pub. No.: US 2011/0173787 A1
(43) Pub. Date: Jul. 21, 2011

(54) MANUFACTURING METHOD OF PIEZOELECTRIC DEVICE

(75) Inventors: Atsushi ONO, Shiojiri-shi (JP); Takayuki KIKUCHI, Okaya-shi (JP)

(73) Assignee: SEIKO EPSON CORPORATION, TOKYO (JP)

(21) Appl. No.: 12/976,252

(22) Filed: Dec. 22, 2010

(30) Foreign Application Priority Data
Jan. 15, 2010 (JP) 2010-006785

(51) Int. Cl. H01L 41/22

(52) U.S. Cl. 29/25.35

(57) ABSTRACT

A manufacturing method of a piezoelectric device includes: forming a lid for sealing a cavity of a package base by forming a recess part and forming a through hole in an inner surface of the recess part in a metal plate; fixing the lid to the package base containing a piezoelectric vibrating reed so that the recess part may project toward the package base side; providing a metal piece in the recess part; decompressing the cavity via the through hole; and closing the through hole by applying a laser to the metal piece to melt the metal piece, wherein, at forming of the lid, the through hole is formed in a direction orthogonal to a thickness direction of the metal plate.

### BACKGROUND

1. Technical Field

The present invention relates to a manufacturing method of a piezoelectric device.

2. Related Art

In related art, piezoelectric devices with piezoelectric vibrating reeds in containers have been used as angular velocity sensors for detecting rotation angular velocities of rotational systems. The piezoelectric devices are used for car navigation systems, detection of shake of still cameras.

Generally, a piezoelectric device employs a structure in which a piezoelectric vibrating reed of quartz or the like is supported by a lead or the like and fixed within a package base and a cavity of the package base is air-tightly sealed by a lid. For example, Patent Document 1 (JP-A-2002-171152) discloses that a metal sphere is irradiated with a beam in vacuum and melted to close a through hole formed in a lid.

One of purposes according to some aspects of the invention is to provide a manufacturing method of a piezoelectric device that can prevent a laser from entering a cavity when a through hole formed in a lid of a package is closed by irradiating a metal piece with the laser.

### SUMMARY

An advantage of some aspects of the invention is to solve at least a part of the problems described above and the invention can be embodied as the following forms or application examples.

### Application Example 1

A manufacturing method of a piezoelectric device according to this application example of the invention includes: forming a lid for sealing a cavity of a package base by forming a recess part and forming a through hole in an inner surface of the recess part in a metal plate; fixing the lid to the package base containing a piezoelectric vibrating reed so that the recess part may project toward the package base side; providing a metal piece in the recess part; decompressing the cavity via the through hole; and closing the through hole by applying a laser to the metal piece to melt the metal piece, wherein, at forming of the lid, the through hole is formed in a direction orthogonal to a thickness direction of the metal plate.

According to the manufacturing method of a piezoelectric device, when the laser is applied from the thickness direction to melt the metal piece, the laser can be prevented from entering the cavity via the through hole and damaging members (the piezoelectric vibrating reed, a lead, or the like) contained in the cavity.

### Application Example 2

This application example is directed to the application example 1, wherein, at forming of the lid, the recess part and the through hole are formed by forming a pair of cut-in parts opposing to each other in the metal plate in a plan view of the metal plate from the thickness direction and pressurizing an area between the pair of cut-in parts of the metal plate.

According to the manufacturing method of a piezoelectric device, no other member than the lid is necessary for formation of the recess part, and the recess part may integrally be formed as a part of the lid. Therefore, the piezoelectric device can be manufactured by a simple method.

### Application Example 3

This application example is directed to the application example 2, wherein, at forming of the lid, the area is recessed in the thickness direction, and thereby, one opening of the through hole is formed by one of the pair of cut-in parts and the other opening of the through hole is formed by the other of the pair of cut-in parts, and the one opening and the other opening are not seen in a plan view of the lid from the thickness direction.

According to the manufacturing method of a piezoelectric device, the laser can reliably be prevented from entering the cavity via the through hole.

### Application Example 4

This application example is directed to any one of the application examples 1 to 3, which further includes performing plating processing at least on the inner surface of the recess part before providing the metal piece.

According to the manufacturing method of a piezoelectric device, wettability of the inner surface of the recess part to the metal piece can be improved.

### Application Example 5

This application example is directed to any one of the application examples 1 to 4, wherein the metal piece has a spherical shape, and a diameter of the metal piece is larger than a depth of the recess part.

According to the manufacturing method of a piezoelectric device, after the metal piece is provided in the recess part, the metal piece can be prevented from entering the cavity via the through hole.

### BRIEF DESCRIPTION OF THE DRAWINGS

The invention will be described with reference to the accompanying drawings, wherein like numbers reference like elements.

FIG. 1 is a perspective view schematically showing a piezoelectric device according to the embodiment.

FIG. 2 is a sectional view schematically showing the piezoelectric device according to the embodiment.

FIG. 3 is a plan view schematically showing a piezoelectric vibrating reed of the piezoelectric device according to the embodiment.

FIG. 4 is a diagram for explanation of a movement of the piezoelectric vibrating reed of the piezoelectric device according to the embodiment.

FIG. 5 is a diagram for explanation of a movement of the piezoelectric vibrating reed of the piezoelectric device according to the embodiment.

FIG. 6 is a plan view schematically showing a manufacturing step of the piezoelectric device according to the embodiment.

FIGS. 7A to 7C are a perspective view and sectional views schematically showing a manufacturing step of the piezoelectric device according to the embodiment.

FIGS. 8A and 8B are a perspective view and a sectional view schematically showing a manufacturing step of the piezoelectric device according to the embodiment.

FIGS. 9A and 9B are a perspective view and a sectional view schematically showing a manufacturing step of the piezoelectric device according to the embodiment.

FIGS. 10A and 10B are a perspective view and a sectional view schematically showing a manufacturing step of the piezoelectric device according to the embodiment.

### DESCRIPTION OF EXEMPLARY EMBODIMENTS

Hereinafter, a preferred embodiment of the invention will be described with reference to the drawings.

### 1. Piezoelectric Device

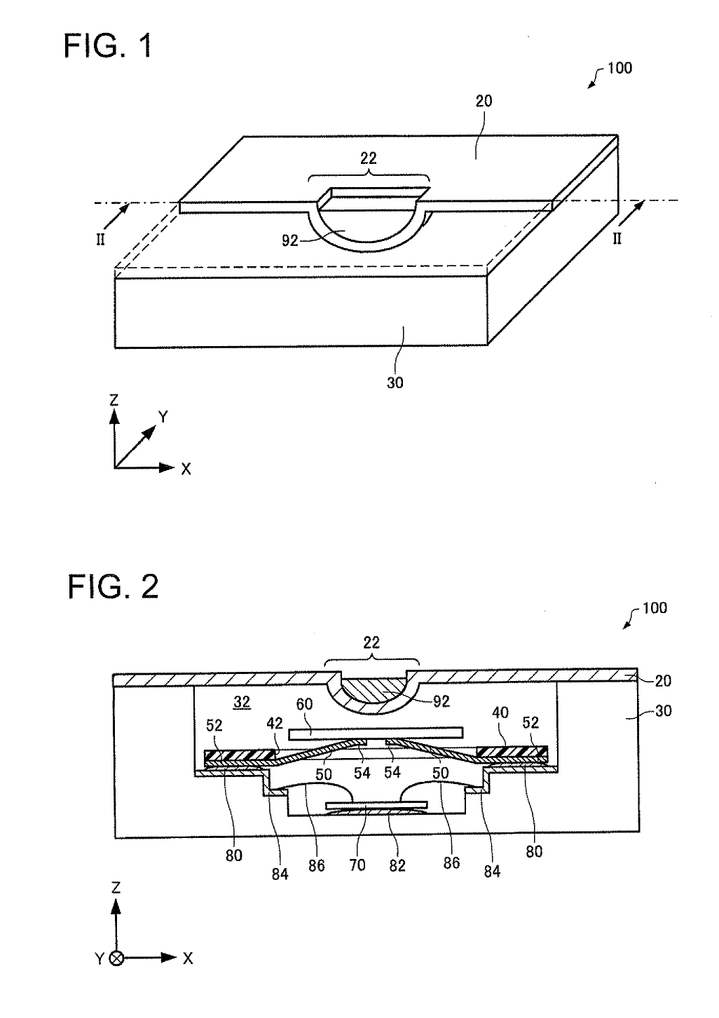

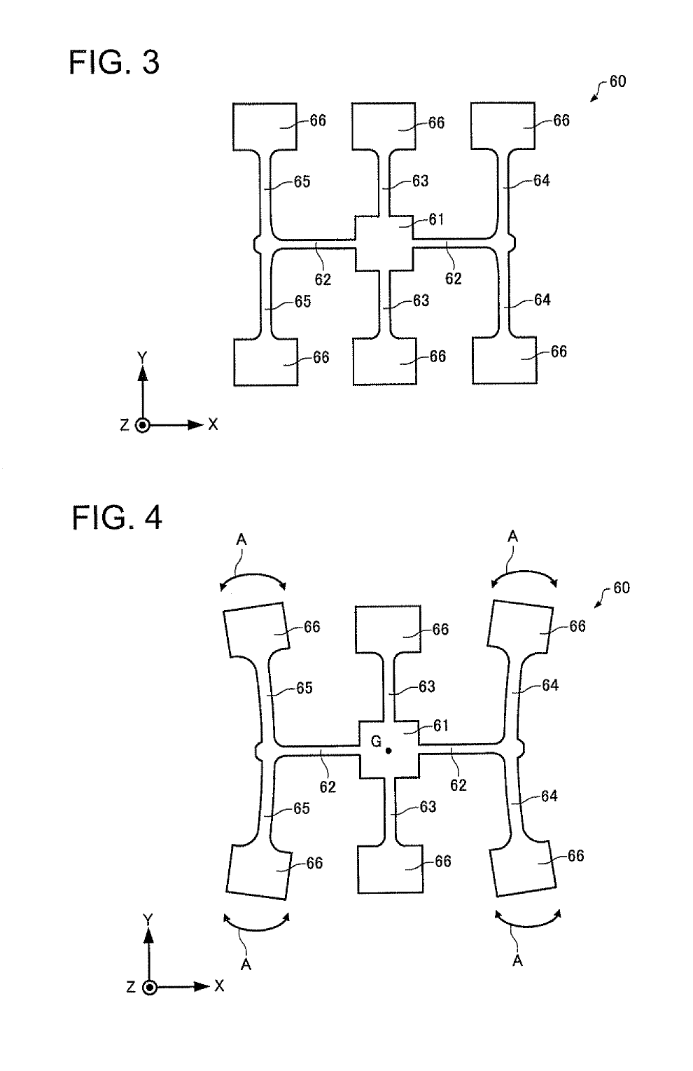

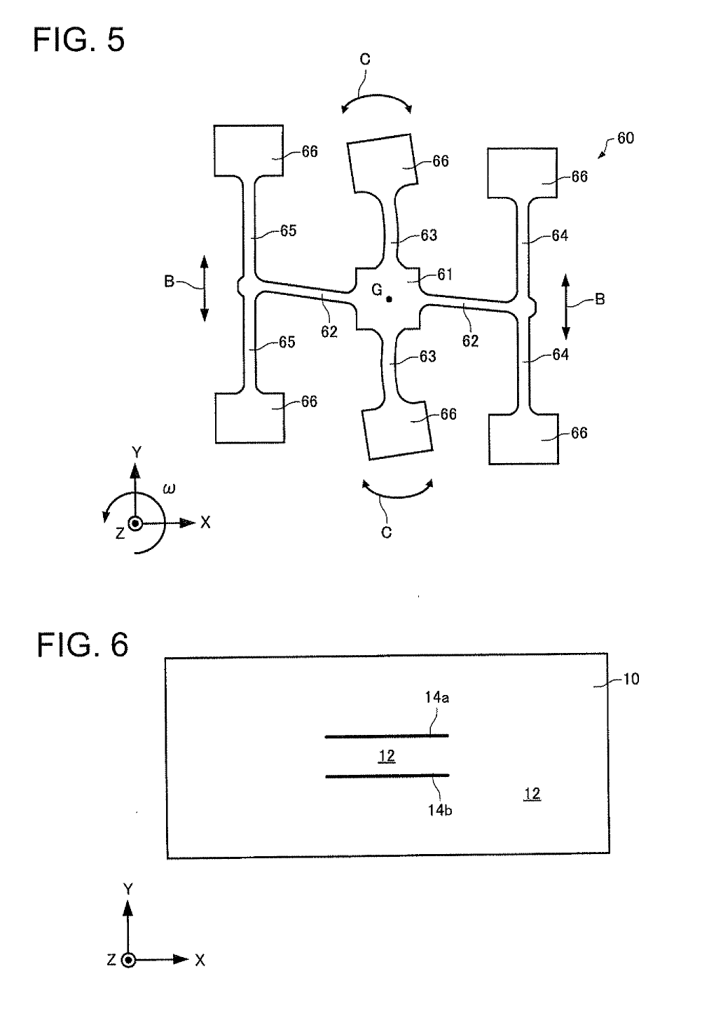

First, a piezoelectric device 100 according to the embodiment will be explained with reference to the drawings. FIG. 1 is a perspective view schematically showing the piezoelectric device 100. FIG. 2 is a sectional view along II-II line of FIG. 1 schematically showing the piezoelectric device 100. FIG. 3 is a plan view schematically showing a piezoelectric vibrating reed 60 of the piezoelectric device 100. FIGS. 4 and 5 are diagrams for explanation of movements of the piezoelectric vibrating reed 60 of the piezoelectric device 100. In FIG. 1, a part of a lid 20 is shown to be transparent for convenience.

As below, as the piezoelectric vibrating reed 60, an example using a so-called double-T piezoelectric vibrating reed will be explained, however, not limited to that, the piezoelectric device 100 may use a tuning fork vibrating reed, a double-ended tuning fork vibrating reed, an AT vibrating reed, a walk vibrating reed, or the like may be used as the piezoelectric vibrating reed 60.

The piezoelectric device 100 may include the lid 20, a package base 30, a support substrate 40, a lead 50, the piezoelectric vibrating reed 60, and an IC chip 70 as shown in FIGS. 1 and 2.

The package base 30 has a cavity 32. The cavity 32 may contain the piezoelectric vibrating reed 60 etc. The cavity 32 is a space for the piezoelectric vibrating reed 60 to move. As a material for the package base 30, for example, ceramic, glass, or the like may be cited.

The lid 20 is fixed onto the package base 30. As a material for the lid 20, for example, a metal such as alloy 42 (an alloy of iron containing 42% of nickel) or kovar (an alloy of iron, nickel, and cobalt) may be cited. The lid 20 and the package base 30 form a package.

In the lid 20, a recess part 22 projecting in a thickness direction (for example, the Z-axis direction) is formed. The recess part 22 projects toward the package base 30 side. Within the recess part 22, a metal piece 92 is formed. As a material for the metal piece 92, for example, gold germanium (Au/Ge), gold tin (Au/Sn), or the like may be cited. By the lid 20 and the metal piece 92, the cavity 32 is air-tightly sealed and placed in a decompression space (for example, a vacuum state). Thereby, the detection sensitivity of the angular velocity of the piezoelectric device 100 may be improved.

The support substrate 40 is contained in the cavity 32. In the example of the drawing, the support substrate 40 is fixed to the package base 30 via the lead 50. As a material for the support substrate 40, for example, a resin such as polyimide may be cited. The support substrate 40 has an opening part 42 penetrating from the upper surface to the lower surface of the support substrate 40.

The lead 50 is contained in the cavity 32. As a material for the lead 50, for example, copper, gold, nickel, or an alloy of them may be cited. In the example of the drawing, the lead 50 extends from the lower surface side of the support substrate 40 through an opening part 42 to the upper surface side of the support substrate 40. An upper surface of one end part 52 of the lead 50 (the end part located at the lower side of the support substrate 40) is bonded to the lower surface of the support substrate 40 by an adhesive, for example. The lower surface of the one end part 52 is bonded to an interconnection 84 formed on the inner surface of the package base 30 by a brazing filler material 80, for example. An upper surface of the other end part 54 of the lead 50 (the end part located at the upper side of the support substrate 40) is bonded to a terminal (not shown) formed on the piezoelectric vibrating reed 60 by thermal compression bonding, for example.

The piezoelectric vibrating reed 60 is contained in the cavity 32. The piezoelectric vibrating reed 60 is supported by the lead 50 above the support substrate 40. As a material for the piezoelectric vibrating reed 60, a piezoelectric material including a piezoelectric single-crystal such as quartz, lithium tantalate, or lithium niobate, a piezoelectric ceramics such as zirconate titanate, or the like may be used. Further, the piezoelectric vibrating reed 60 may have a structure in which a piezoelectric thin film of zinc oxide, aluminum nitride, or the like sandwiched between electrodes is formed in a part of the surface of a silicon semiconductor.

The piezoelectric device 100 having the piezoelectric vibrating reed 60 may utilize variations in frequency of the piezoelectric vibrating reed 60 in response to a physical quantity to function as a sensor that detects the physical quantity. More specifically, the piezoelectric device 100 may function as a gyro sensor that detects stress generated by the acceleration, Coriolis force generated by the angular velocity and the like.

As shown in FIG. 3, the piezoelectric vibrating reed 60 includes a base part 61, a pair of coupling arms 62, a pair of detection vibrating arms 63, a pair of first driving and vibrating arms 64, and a pair of second driving and vibrating arms 65.

The pair of coupling arms 62 extend from the base part 61 in opposite directions to each other along the X-axis. The pair of detection vibrating arms 63 extend from the base part 61 in opposite directions to each other along the Y-axis. The pair of first driving and vibrating arms 64 extend from one of the pair of coupling arms 62 in opposite directions to each other along the Y-axis. The pair of second driving and vibrating arms 65 extend from the other of the pair of coupling arms 62 in opposite directions to each other along the Y-axis.

In the example of the drawing, weight parts 66 are formed on the ends of the vibrating arms 63, 64, 65. The width of the weight parts 66 (the size in the X-axis direction) is larger than the widths of the vibrating arms 63, 64, 65. Thereby, the detection sensitivity of the piezoelectric device 100 may be improved.

Under the condition with no angular velocity, when voltages are applied to drive electrodes (not shown) formed on the driving and vibrating arms 64, 65, the driving and vibrating arms 64, 65 perform flexural vibrations in directions indicated by arrows A as shown in FIG. 4. Concurrently, the first driving and vibrating arm 64 and the second driving and vibrating arm 65 perform line-symmetric vibrations with respect to a line (not shown) along the Y-axis direction passing through the center of gravity G of the piezoelectric vibrating reed 60. Accordingly, the base part 61, the coupling arms 62, and the detection vibrating arms 63 hardly vibrate.

Under the condition that the driving and vibrating arms 64, 65 perform drive vibrations in the A direction, when an angular velocity ω around the Z-axis is applied to the piezoelectric vibrating reed 60, the piezoelectric vibrating reed 60 performs vibrations as shown in FIG. 5. That is, Coriolis force in the directions of arrows B acts on the driving and vibrating arms 64, 65 and the coupling arms 62 forming the drive vibration system, new vibrations are excited. The vibrations in the directions of the arrows B are circumferential vibrations with respect to the center of gravity G. Further, simultaneously, for the detection vibrating arms 63, detection vibrations in the directions of arrows C are excited in response to the vibration of the arrows B. Then, the detection electrodes (not shown) formed in the detection vibrating arms 63 detect the distortion of the piezoelectric material generated by the vibrations, and thereby, the angular velocity is obtained.

As shown in FIG. 2, the IC chip 70 is contained in the cavity 32. In the example of the drawing, the IC chip 70 is mounted on the bottom surface (the inner bottom surface) of the package base 30 by a brazing filler material 82. The IC chip 70 is electrically connected to the interconnection 84 formed on the package base 30 by a wire 86, for example. Though not shown, the IC chip 70 may be provided outside of the package base 30. In the IC chip 70, a drive circuit for driving and vibrating the piezoelectric vibrating reed 60 and a detection circuit for detecting detection vibration generated in the piezoelectric vibrating reed 60 when an angular velocity is applied thereto are incorporated.

### 2. Manufacturing Method of Piezoelectric Device

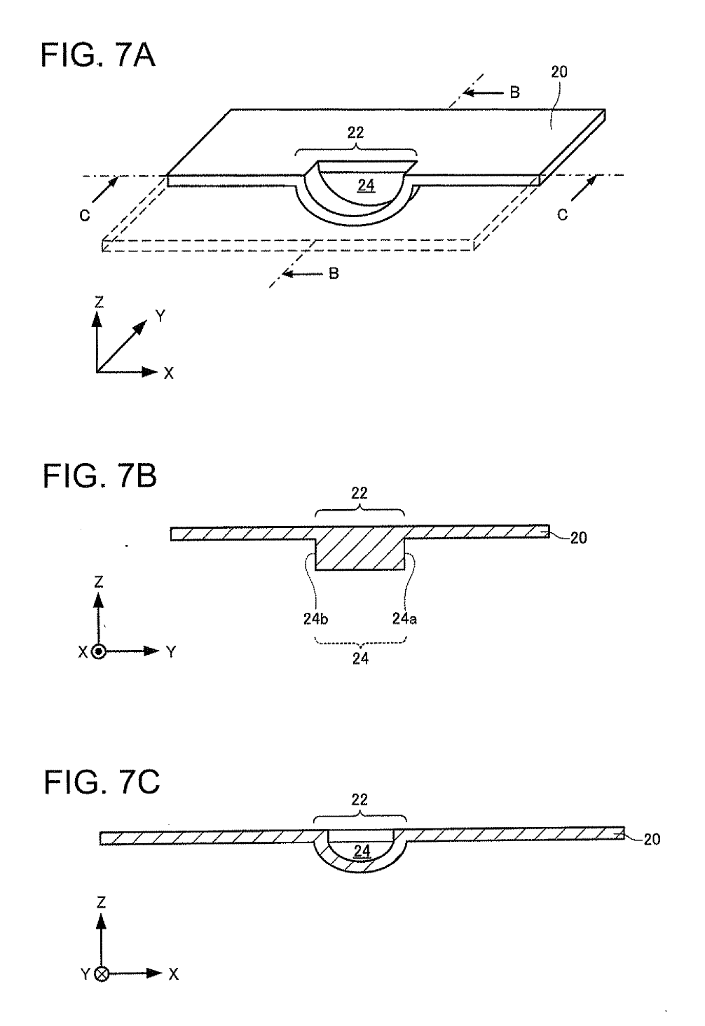

Next, a manufacturing method of the piezoelectric device 100 according to the embodiment will be explained with reference to the drawings. FIG. 6 is a plan view schematically showing a manufacturing step of the piezoelectric device 100 according to the embodiment. FIGS. 7A to 10B schematically show manufacturing steps of the piezoelectric device 100. In FIGS. 7A to 10B, FIGS. 7A, 8A, 9A, and 10A are perspective views, FIGS. 7B, 8B, 9B, and 10B are sectional views along B-B line, and FIG. 7C is a sectional view along C-C line of FIG. 7A. Further, in the perspective views of FIGS. 7A to 10B, a part of the lid 20 is shown to be transparent for convenience.

As shown in FIG. 6, a metal plate 10 to be the lid 20 is prepared, and cut-in parts 14a, 14b are formed in the metal plate 10. The metal plate 10 has a thickness in the Z-axis direction, for example, and the planar shape of the metal plate 10 is developed in the XY plane.

The cut-in parts 14a, 14b are formed to oppose to each other in a plan view from the thickness direction (Z-direction) of the metal plate 10. In the example of the drawing, the cut-in parts 14a, 14b are in parallel to each other. The cut-in parts 14a, 14b may be formed to penetrate a principle surface (for example, a front surface) on one side of the metal plate 10 and a principle surface (for example, a rear surface) on the other side. The method of forming the cut-in parts 14a, 14b is not particularly limited, but press working may be cited, for example.

As shown in FIGS. 7A to 7C, the recess part 22 and a through hole 24 are formed in the metal plate 10 to form the lid 20. More specifically, pressure is applied to an area 12 (see FIG. 6) between the cut-in parts 14a, 14b of the metal plate 10 from the Z-axis direction. Thereby, the recess part 22 projecting in the Z-axis direction is formed. Concurrently, the through hole 24 is formed in the inner surface of the recess part 22 by the cut-in parts 14a, 14b.

Specifically, the area 12 is recessed in the Z-axis direction, and, as shown in FIG. 7B, for example, one opening 24a of the through hole 24 is formed by one cut-in part 14a and the other opening 24b of the through hole 24 is formed by the other cut-in part 14b. The direction of the through hole 24 is a direction orthogonal to the Z-axis direction (the Y-axis direction in the example of the drawing). Here, “direction of the through hole 24” may also be a direction in which at least a part of the one opening 24a and at least a part of the other opening 24b are seen overlapping. For example, if the lid 20 is seen in the plan view from the Z-axis direction, the first opening 24a and the second opening 24b are formed not to be seen.

The sectional shape of the recess part 22 is a U-shape, for example, as shown in FIG. 7C. The sectional shape of the through hole 24 is a semicircular shape, for example.

The pressurization of the area 12 may be performed by spinning, for example. That is, though not shown in the drawing, the metal plate 10 may be worked by fixing it using a tool and pressing the area 12 from the one principle surface side into a die set at the other principle surface by punching. For example, the plate may be worked by gradually changing punches for use in the smaller diameter to the larger diameter. Thereby, the dimensional accuracy of the recess part 22 may be improved.

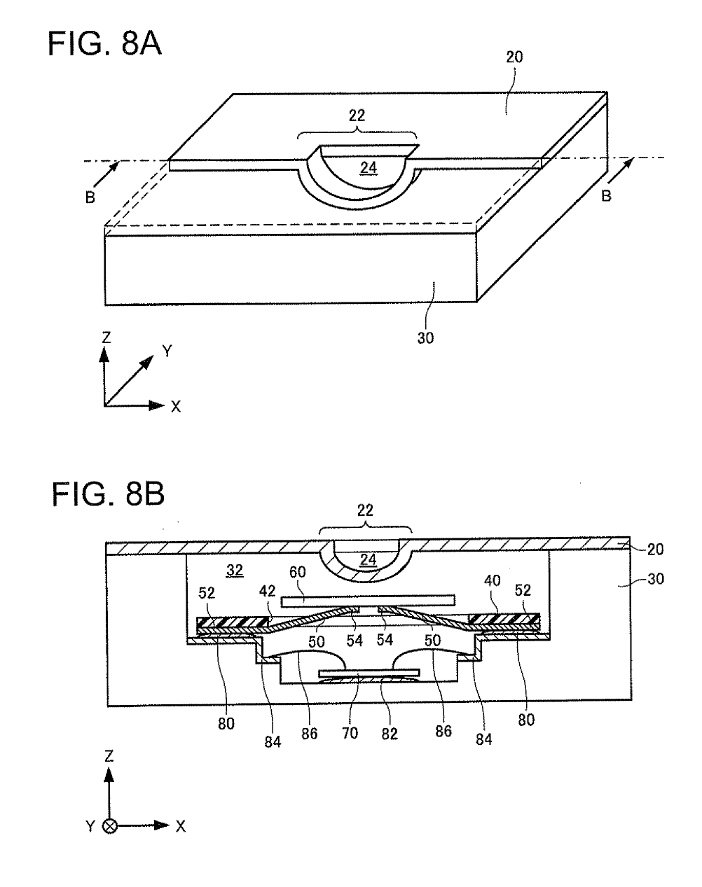

As shown in FIGS. 8A and 8B, the lid 20 is fixed onto the package base 30 so that the recess part 22 may project toward the package base 30 side. The fixing (joining) of the package base 30 and the lid 20 is performed by seam welding, plasma welding, ultrasonic welding, an adhesive, or the like. In the cavity 32 of the package base 30, for example, the support substrate 40, the lead 50, the piezoelectric vibrating reed 60, and the IC chip 70 are contained.

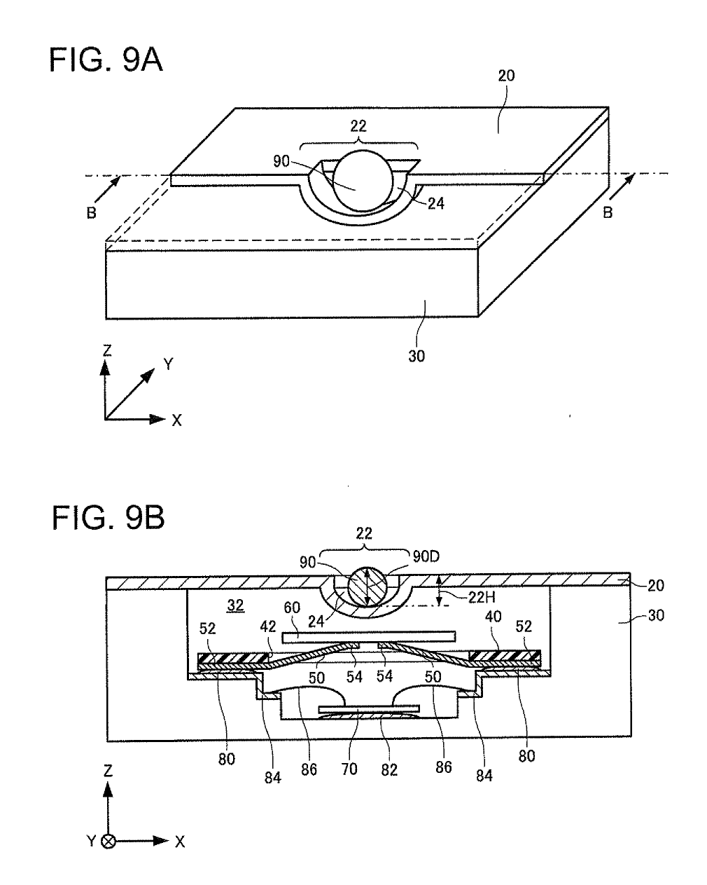

As shown in FIGS. 9A and 9B, a metal piece 90 is provided in the recess part 22. The shape of the metal piece 90 is a spherical shape, for example. The diameter 90D of the metal piece 90 is larger than the depth 22H of the recess part 22 (the size in the Z-axis direction), for example. The metal piece 90 may be formed by the same material as that of the metal piece 92 shown in FIGS. 1 and 2.

Note that, before the metal piece 90 is provided in the recess part 22, plate processing may be performed on the inner surface (on which the metal piece 90 is to be provided) of the recess part 22. As more specific plate processing, gold plating processing or the like may be cited. The plate processing may be performed after the recess part 22 is formed or before the recess part 22 is formed as long as the time is before the metal piece 90 is provided in the recess part 22.

Then, the cavity 32 is decompressed via the through hole 24. Thereby, the cavity 32 may be brought into the vacuum state (high vacuum state at the high degree of vacuum).

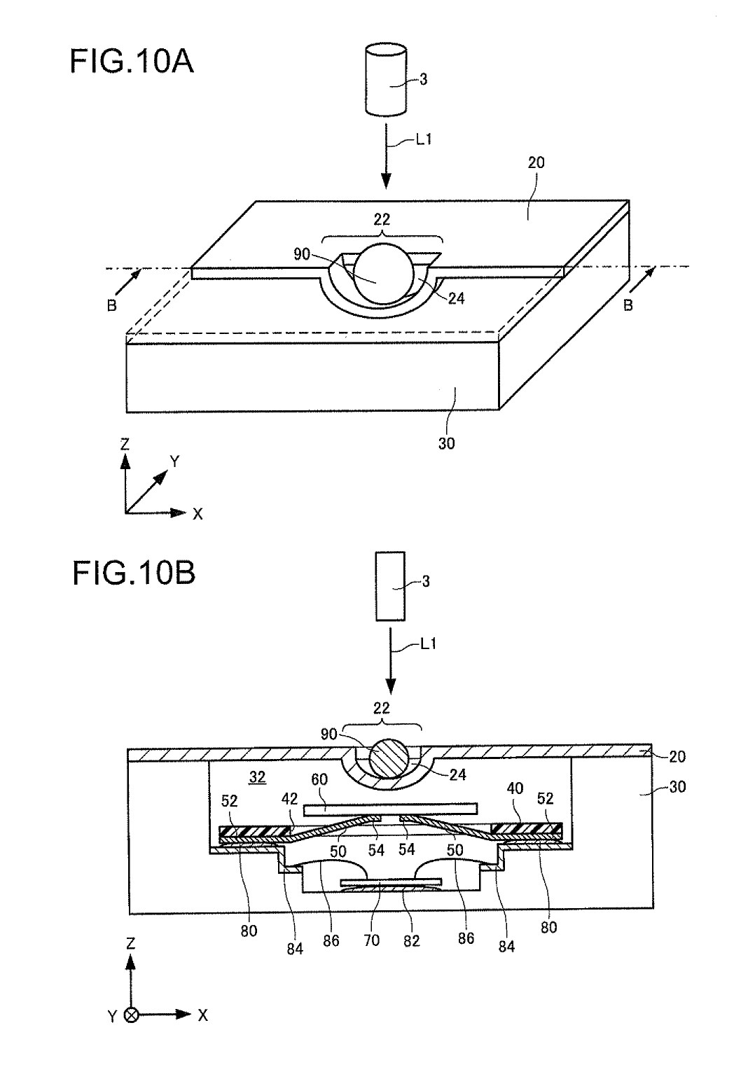

As shown in FIGS. 10A and 10B, while the cavity is held in the high vacuum state, a laser L1 is applied to the metal piece 90. Then, the metal piece 90 is melted to close the through hole 24 as shown in FIGS. 1 and 2. Thereby, the cavity 32 is air-tightly sealed. The shape of the melted metal piece 92 may not particularly be limited as long as it may air-tightly seal the cavity 32.

The laser L1 is applied from a laser application unit 3. The laser L1 is applied to travel in the Z-axis direction. The condition of the laser L1 is not particularly limited as long as the metal piece 90 may be melted, and, for example, fundamental of a YAG laser (wavelength 1064 nm) may be used.

The piezoelectric device 100 may be manufactured through the above described steps.

The manufacturing method of the piezoelectric device 100 according to the embodiment has the following characteristics, for example.

According to the manufacturing method of the piezoelectric device 100, the through hole 24 for decompressing the cavity 32 may be formed to be directed toward the direction (for example, the Y-axis direction) orthogonal to the thickness direction (Z-axis direction) of the metal plate 10. Accordingly, when the laser L1 is applied from the Z-axis direction to melt the metal piece 90, the laser L1 may be prevented from entering the cavity 32 via the through hole 24 and damaging the members (the piezoelectric vibrating reed 60, the lead 50, etc.) contained in the cavity 32.

According to the manufacturing method of the piezoelectric device 100, the through hole 24 may be formed in the lid 20. Accordingly, the package base 30 may be made smaller (that is, the piezoelectric device 100 may be made smaller) compared to the case where the through hole for decompressing the cavity is formed in the bottom surface of the package base. Since the IC chip is formed on the bottom surface of the package base, for example, in the case where the through hole is formed in the bottom surface of the package base, it is necessary to secure another area and the package base may be larger.

According to the manufacturing method of the piezoelectric device 100, the recess part 22 and the through hole 24 may be formed by decompressing the area 12 between the cut-in parts 14a, 14b. That is, no other member than the lid 20 is necessary for formation of the recess part 22, and the recess part may integrally be formed as a part of the lid 20. Therefore, the piezoelectric device 100 may be manufactured by a simple method.

According to the manufacturing method of the piezoelectric device 100, the through hole 24 may be formed so that the first opening 24a and the second opening 24b may not be seen if the lid 20 is seen in the plan view from the Z-axis direction. Thereby, the laser L1 may reliably be prevented from entering the cavity 32 via the through hole 24.

According to the manufacturing method of the piezoelectric device 100, plating processing may be performed on at least the inner surface of the recess part 22. Thereby, wettability of the inner surface of the recess part 22 to the metal piece 90 (metal piece 92) may be improved.

According to the manufacturing method of the piezoelectric device 100, the diameter of the metal piece 90 having the spherical shape is larger than the depth of the recess part 22. Thereby, after the metal piece 90 is provided in the recess part 22, the metal piece 90 may be prevented from entering the cavity 32 via the through hole 24.

As described above, the embodiment of the invention has been explained in detail, and it would be understood by the person skilled in the art that a lot of changes may be made without substantively departing from the new matter and effects of the invention. Therefore, all of the modified examples may be within the range of the invention.

The entire disclosure of Japanese Patent Application No: 2010-006785, filed Jun. 15, 2010 is expressly incorporated by reference herein.

What is claimed is:

1. A manufacturing method of a piezoelectric device comprising:
forming a lid for sealing a cavity of a package base by forming a recess part and forming a through hole in an inner surface of the recess part in a metal plate;
fixing the lid to the package base containing a piezoelectric vibrating reed so that the recess part may project toward the package base side;
providing a metal piece in the recess part;
decompressing the cavity via the through hole; and
closing the through hole by applying a laser to the metal piece to melt the metal piece,
wherein, at forming of the lid, the through hole is formed in a direction orthogonal to a thickness direction of the metal plate.

2. The manufacturing method of a piezoelectric device according to claim 1, wherein, at forming of the lid, the recess part and the through hole are formed by forming a pair of cut-in parts opposing to each other in the metal plate in a plan view of the metal plate from the thickness direction and pressurizing an area between the pair of cut-in parts of the metal plate.

3. The manufacturing method of a piezoelectric device according to claim 2, wherein, at forming of the lid, the area is recessed in the thickness direction, and thereby, one opening of the through hole is formed by one of the pair of cut-in parts and the other opening of the through hole is formed by the other of the pair of cut-in parts, and
the one opening and the other opening are not seen in a plan view of the lid from the thickness direction.

4. The manufacturing method of a piezoelectric device according to claim 1, further comprising performing plating processing at least on the inner surface of the recess part before providing the metal piece.

5. The manufacturing method of a piezoelectric device according to claim 1, wherein the metal piece has a spherical shape, and
a diameter of the metal piece is larger than a depth of the recess part.
